(19) United States
(12) Patent Application Publication
(10) Pub. No.: US 2004/0168631 A1
(43) Pub. Date: Sep. 2, 2004

(54) Plasma processing apparatus having protection members

(76) Inventors: Fumikane Honjou, Okayama-shi (JP); Kazunori Hasegawa, Bizen-shi (JP); Hiroki Okunishi, Osakayama-shi (JP)

Correspondence Address: MCDERMOTT, WILL & EMERY, 600 13th Street, N.W., Washington, DC, 20005-3096, US

(21) Appl. No.: 10/736,783

(22) Filed: Dec. 17, 2003

(30) Foreign Application Priority Data
Dec. 17, 2002 (JP) 2002-364861
Nov. 17, 2003 (JP) 2003-386910

(51) Int. Cl. C23C 16/00

(52) U.S. Cl. 118/715

(57) ABSTRACT

Disclosed is a plasma processing apparatus provided with a plasma chamber in which a plasma is generated by electron cyclotron resonance, and a sample chamber for housing a sample to be processed with the plasma. The plasma chamber is provided with a protection tube for protecting the inner walls of the plasma chamber from deposition of products resulting from the plasma processing. The protection tube is composed of a plurality of sub-tubes formed in relation to the temperature distribution at the time of the plasma processing.

This application is based on applications No. 2002-364861 and No. 2003-386910 filed in Japan, the contents of which are hereby incorporated by reference.

### BACKGROUND OF THE INVENTION

(1) Field of the Invention

The present invention relates to a plasma processing apparatus generally for thin film forming using a plasma. More particularly, the present invention relates to technology to prevent inside the plasma processing apparatus from deposition of products such as silicon oxide.

(2) Description of the Related Art

In recent manufacturing of electronic devices such as semiconductor circuits, it is common to employ sputtering and etching using a high-density plasma generated by electron cyclotron resonance (ECR).

Take an ECR sputtering as an example, a plasma by ECR dissociates ions from a gas or a mixture gas (argon gas, for example) and the resulting ions collide with a target. The collision sputters metallic atoms from the target. As a result, a film is formed on a sample by deposition of the metallic atoms and of molecules that are formed by reaction of the metallic atoms with a gas present in a film-forming chamber.

FIG. 1 is a cross-sectional view showing the structure of an exemplary ECR sputtering apparatus employed for ECR sputtering. As shown in FIG. 1, the ECR sputtering apparatus 6 is composed of a film-forming chamber 601 and a plasma chamber 607 that are next to each other. Provided inside the film-forming chamber 601 is a sample stage 604 for placing a sample 603 thereon.

The film-forming chamber 601 is provided with a plasma inlet 606 on a side thereof adjacent to the plasma chamber 607, so that the two chambers are brought into communication. Disposed to surround the plasma inlet 606 is a ring-shaped metal target 605 that is made of a solid material containing silicon. The metal target 605 serves as a source material for a film to be formed on the sample 603.

A microwave 608 is introduced into the plasma chamber 607 through a waveguide tube 609. Provided between the plasma chamber 607 and the waveguide tube 609 is a microwave window 610 that is made of quartz glass. The microwave window 610 hermetically seals the plasma chamber 607 at an opening formed through a side thereof on which the waveguide tube 609 is provided.

The film-forming chamber 601 is further provided with a discharge outlet 602. A gas present in the film-forming chamber 601 and the plasma chamber 607 are evacuated through the discharge outlet 602 by a vacuum device (not illustrated), so that the film-forming chamber 601 and the plasma chamber 607 are maintained under vacuum. At this stage, a source gas for generating a plasma is introduced into the plasma chamber 607 through a gas inlet 611 provided through a wall thereof.

Disposed to surround the plasma chamber 607 is an exciting coil 612. When the source gas is introduced into the plasma chamber 607, the exciting coil 612 generates a magnetic field in the plasma chamber 607, so that a discharge occurs by electronic cyclotron resonance. As a result, a high-density plasma is generated and argon ions are subsequently generated.

The thus generated argon ions travel from the plasma chamber 607 to the film-forming chamber 601 through the plasma inlet 606.

Since a negative potential is applied the metal target 605, an electric field is generated. By the action of the eclectic field, the argon ions are attracted to and collide with the metal target 605. Upon the collisions, silicon atoms sputter from the metal target 605 and deposit on the sample 603. In addition, molecules generated by reaction of the silicon atoms with the gas present in the film-forming chamber 601 also deposit on the sample 603.

As a result, a film is formed on the sample 603 (see, for example, JP unexamined patent application publication No. 01-306558 (pages 2-4 and FIG. 1)).

During the film forming on the sample 603, silicon atoms sputtered from the metal target 605 deposit not only on the sample 603 but also on inner walls of the plasma chamber 607, i.e., inner walls of the ECR sputtering apparatus. To protect the inner walls from the deposition, protection plates 613 and 614 and a protection tube 620 are provided inside the plasma chamber 607.

The protection tube 620 is made with a quartz tube that is cylindrically shaped. The protection plate 613 is a quartz-made circular plate having a circular hole, and the protection plate 614 is a quartz-made circular plate having a rectangular hole. By the presence of the protection tube 620 and the protection plates 613 and 614, the silicon atoms deposit on the protection tube and plates, so that the inner walls of the plasma chamber 607 are shielded from the deposition. It should be noted here that a film of silicon oxide and other products is formed on the surface of the protection tube 620, and the deposition film grows by repeating the film-forming processing.

On the other hand, at the time when a plasma is generated, the temperature across the plasma chamber 607 is the highest in the central area, and lower and lower in the areas farther away from the central area. Accordingly, the temperature across the protection tube 620 is the highest at a part closest to the central area of the plasma chamber 607, and lower and lower at parts farther away from the central area. This difference in the temperatures produces thermal stress across the protection tube 620.

When the ECR sputtering apparatus repeats the film-forming processing, resulting thermal fatigue leads to breakage of the protection tube 620. On the breakage, flakes of the silicon oxide and other products having been deposited on the protection tube 620 are scattered around as well as broken pieces of the protection tube 620. As these flakes and pieces obstruct migration of the argon ions, the ECR sputtering apparatus eventually loses capability of forming a film on the sample surface.

Such a problem is solved by replacing the protection tube 620 with a new one, so that the film-forming capability is recovered. However, in order to replace the protection tube 620, the hermetical seal of the film-forming chamber 601 is inevitably broken, so that evacuation and water removal of the film-forming chamber 601 need to be carried out after the replacement.

The evacuation and water removal is time-consuming work. In addition, if the protection tube 620 is frequently replaced, the manufacturing cost of the protection tube 620 increases, which is undesirable in terms of cost. This problem arises not only with the ECR sputtering apparatus but generally with all the plasma processing apparatuses using electron cyclotron resonance, such as ECR etching apparatuses, and also with all the plasma processing apparatuses using a high-density plasma.

This is because variations of temperatures across a plasma chamber occur no matter in what way a plasma is generated, and the variations are greater as the density of the plasma is higher and thus as the resulting temperatures are higher.

For example, when the plasma density is 10¹¹ ions/cm³ or so, the resulting temperatures are estimated to be 600° C. or higher. Such high temperatures cause severe thermal effect on a protection tube.

### SUMMARY OF THE INVENTION

The present invention is made in view of the problems noted above, and aims to provide a plasma processing apparatus which does not require replacement of protection members as frequently as a conventional apparatus.

To achieve the above aim, the present invention provides a plasma processing apparatus including: a plasma chamber in which a high-density plasma is generated; a sample chamber in communication with the plasma chamber for housing a sample to be processed using the plasma; and a protection tube for protecting an inner wall of the plasma chamber from deposition of a product that results from the plasma processing. Here, the protection tube is composed of a plurality of pieces formed in relation to a distribution of temperatures in the plasma chamber at a time of the plasma processing.

With the structure stated above, thermal stress due to the temperature difference across the protection tube during the plasma processing is released. Consequently, breakage of the protection tube is prevented, so that the protection tube replacement is required less frequently. This leads to reduction in running costs of the plasma processing apparatus.

Further, the plasma chamber may be tubular in shape. The protection tube may be tubular in shape and inserted in the plasma chamber. Each of the plurality of pieces maybe a tubular member disposed in an axial direction of the protection tube.

With the structure stated above, the thermal stress applied to the protection tube is not localized but distributed, so that the risk of protection tube breakage is further reduced.

Further, each of the plurality of pieces may be shorter in length than a piece disposed at a location where a gradient of the temperatures at the time of the plasma processing is smaller.

With the structure stated above, the temperature difference with in each piece (i.e., tubular member) constituting the protection tube is made smaller, so that thermal stress applied to each tubular member is suppressed. Consequently, breakage of each tubular member is prevented, and thus breakage of the protection tube is prevented as well.

Further, the protection tube may be provided with at least one groove formed on an inner wall thereof in parallel with an axis of the protection tube.

With the structure stated above, the distortion due to the stress caused by a deposition film formed on the inner wall of the protection tube is absorbed, and thus the distortion of the quartz due the stress is efficiently absorbed. Consequently, breakage of the protection tube is prevented.

Further, the protection tube may be provided with a plurality of grooves formed on the inner wall thereof in parallel with an axis of the protection tube at substantially equal circumferential intervals.

With the structure stated above, the stress due to expansion of the deposition film is not localized but distributed. Consequently, breakage of the protection tube is prevented. Here, it is desirable that the grooves extend perpendicularly to the direction of the stress applied due to the deposition film. Consequently, the stress is effectively released.

Further, the protection tube may be made of quartz.

With the arrangement stated above, the protection tube is made to resistant to high temperatures caused at the time of the plasma processing, so that the inner walls of the plasma chamber are protected from deposition of useless products. Further, the protection tube with the structure stated above is less prone to breakage.

Further, the sample may be subjected to sputtering using the plasma.

With the structure stated above, the protection tube disposed in the sputtering apparatus is made to less prone to breakage. Consequently, the productivity of the sputtering apparatus improves.

Further, the plasma maybe an electron cyclotron resonance plasma.

With the structure stated above, damage to the sample is suppressed, so that the apparatus is capable of manufacturing high-quality products by the plasma processing. In addition, cost advantage, such as improvement in the manufacturing yield is achieved.

Alternatively, the plasma may be an inductively coupled plasma or a helicon wave plasma.

With any of the structures stated above, the effect of the present invention is achieved.

In another aspect, the present invention provides a plasma processing apparatus including: a plasma chamber in which a high-density plasma is generated; a sample chamber in communication with the plasma chamber for housing a sample to be processed using the plasma; and a protection tube for protecting an inner wall of the sample chamber from deposition of a product that results from the plasma processing. Here, the protection tube is composed of a plurality of pieces formed in relation to a distribution of temperatures in the sample chamber at the time of the plasma processing.

With the structure stated above, the protection tube protects the inner walls of the sample chamber from deposition of useless products, and the thermal stress across the protection tube due to the temperature gradient during the plasma processing is released. Consequently, breakage of the protection tube is prevented, so that the protection tube replacement is not required as frequently as that would otherwise be required. This leads to reduction in running costs of the plasma processing apparatus.

Further, the sample chamber may be tubular in shape. The protection tube may be tubular in shape and inserted in the plasma chamber. Each of the plurality of pieces may be a tubular member disposed in an axial direction of the protection tube.

With the structure stated above, the thermal stress applied to the protection tube is not localized but distributed, so that the risk of protection tube breakage is further reduced.

Further, each of the plurality of pieces may be shorter in length than a piece disposed at a location where a gradient of the temperatures at the time of the plasma processing is smaller.

With the structure stated above, the temperature difference within each piece (i.e., tubular member) constituting the protection tube is made smaller, so that thermal stress applied to each tubular member is suppressed. Consequently, breakage of each tubular member is prevented, and thus breakage of the protection tube is prevented as well.

Further, the protection tube may be provided with at least one groove formed on an inner wall thereof in parallel with an axis of the protection tube.

With the structure stated above, the distortion due to the stress caused by a deposition film formed on the inner wall of the protection tube is absorbed, and thus the distortion of the quartz due the stress is efficiently absorbed. Consequently, breakage of the protection tube is prevented.

Further, the protection tube may be provided with a plurality of grooves formed on the inner wall thereof in parallel with an axis of the protection tube at substantially equal circumferential intervals.

With the structure stated above, the stress due to expansion of the deposition film is not localized but distributed. Consequently, breakage of the protection tube is prevented. Similarly to the above, it is desirable that the grooves extend perpendicularly to the direction of the stress applied due to the deposition film.

Further, the protection tube may be made of quartz.

With the arrangement stated above, the protection tube is made to resistant to high temperatures caused at the time of the plasma processing, so that the inner walls of the plasma chamber are protected from deposition of useless products. Further, the protection tube with the structure stated above is less prone to breakage.

Further, the sample may be subjected to etching using the plasma.

With the structure stated above, the protection tube disposed in the etching apparatus is made to less prone to breakage. Consequently, the productivity of the etching apparatus improves.

Further, the sample may be subjected to chemical vapor deposition using the plasma.

With the structure stated above, the protection tube disposed in the plasma CVD (Chemical Vapor Deposition) apparatus is made to less prone to breakage. Consequently, the productivity of the plasma CVD apparatus improves.

Further, the plasma may be an electron cyclotron resonance plasma.

With the structure stated above, damage to the sample is suppressed, so that the apparatus is capable of manufacturing high-quality products by the plasma processing. In addition, cost advantage, such as improvement in the manufacturing yield is achieved.

Alternatively, the plasma is an inductively coupled plasma or a helicon wave plasma.

With any of the structures stated above, the effect of the present invention is achieved.

As described above, the plasma processing apparatus according to the present invention achieves an effect of prolonging the useful life of the protection tube. The protection tube is disposed protect inside the plasma processing apparatus from deposition of silicon oxide and other products that result from plasma processing, such as thin-film forming. Consequently, the present invention is highly useful to reduce costs of the plasma processing.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1 is a cross-sectional view showing the structure of an exemplary ECR sputtering apparatus according to prior art;

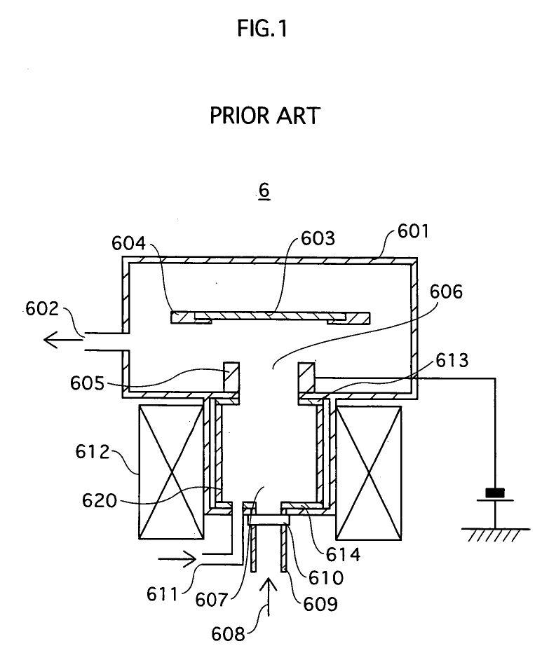

FIG. 2 is a cross-sectional view showing the structure of an ECR sputtering apparatus according to an embodiment of the present invention;

FIGS. 3 are views showing the structure of a protection tube 2 according to the embodiment (FIG. 3A is an external oblique view of the protection tube 2, FIG. 3B is a cross-sectional view of the protection tube 2 taken along a plane containing the tube axis, and FIG. 3C is a top view showing the protection tube 2 seen from the direction of a film-forming chamber 101);

FIG. 4 is a cross-sectional view showing an exemplary ICP sputtering apparatus provided with a protection tube according to a modification (5) of the present invention;

FIG. 5 is a cross-sectional view showing an exemplary reactive ion beam etching apparatus provided with a protection tube according to a modification (6) of the present invention; and

FIG. 6 is a cross-sectional view showing the structure of an exemplary ECR plasma CVD apparatus according to the modification (6) of the present invention.

### DESCRIPTION OF THE PREFERRED EMBODIMENTS

Now, description is given, with reference to the accompanying drawings, to a plasma processing apparatus according to a preferred embodiment of the present invention taking an ECR sputtering apparatus as an example.

1. Structure of ECR Sputtering Apparatus

An ECR sputtering apparatus according to the present embodiment is generally similar in structure to the conventional ECR sputtering apparatus described above.

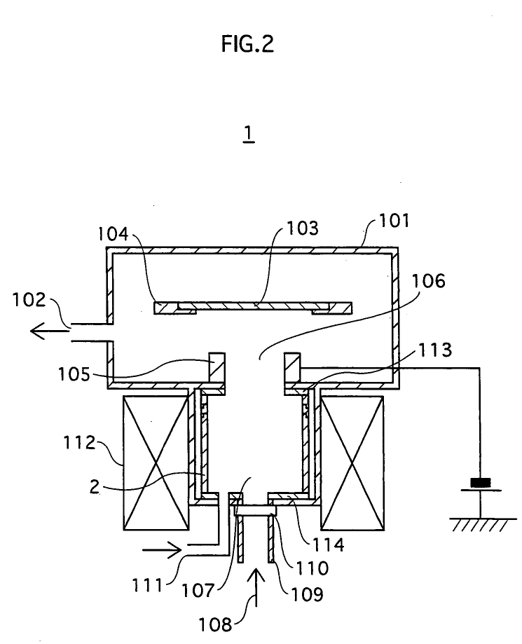

FIG. 2 is a cross-sectional view showing the structure of the ECR sputtering apparatus 1 according to the present embodiment. As shown in FIG. 2, the ECR sputtering apparatus 1 is composed of a film-forming chamber 101, a discharge outlet 102, a sample stage 104, a metal target 105, a plasma inlet 106, a plasma chamber 107, a waveguide tube 109, a microwave window 110, a gas inlet 111, an exciting coil 112, protection plates 113 and 114, and a protection tube 2.

The film-forming chamber 101 is an air-tight vessel for housing a sample 103 on which a thin film is to be formed. A gas present in the film-forming chamber 101 is evacuated by suction through the discharge outlet 102. The sample stage 104 is disposed inside the film-forming chamber 101, and the sample 103 is placed on the sample stage 104.

Further, through a wall of the film-forming chamber 101 that is adjacent to the plasma chamber 107, a circular opening is formed as the plasma inlet 106 for introducing a plasma from the plasma chamber 107. In addition, the metal target 105, which takes a shape of a short-length tube, is disposed on the same wall of the film-forming chamber 101 so as to surround the plasma inlet 106.

The metal target 105 is supported by a shield case (not illustrated). Further, a negative potential is applied to the metal target 105, so that the metal target 105 is at the potential lower than that of the plasma chamber 107.

The plasma chamber 107 is a tubular shaped vessel used to generate a plasma by electron cyclotron resonance. The plasma chamber 107 is also provided with a circular opening formed, as a part of the plasma inlet 106, at the bottom that is adjacent to the film-forming chamber 101.

At the other bottom of the plasma chamber 107, a rectangular opening is formed for introducing a microwave 108 through the waveguide tube 109. The rectangular opening is covered by the microwave window 110 that is made of quartz glass, so that the film-forming chamber 101 and the plasma chamber 107 are hermetically sealed.

Further, another opening is formed at the same bottom of the plasma chamber 107 for introducing an argon gas.

In order to generate a magnetic field inside the plasma chamber 107, and to subsequently generate discharge by electron cyclotron resonance, the plasma chamber 107 is surrounded by the exciting coil 112. Similarly to the plasma chamber 607 of the ECR sputtering apparatus 6 described above, the plasma chamber 107 is provided with the protection plates 113 and 114 and the protection tube 2 disposed therein so as to protect the inner walls of the plasma chamber 107 from deposition of silicon oxide and other products.

The protection plate 113 is a quartz-made circular plate having a circular opening at a location corresponding to the plasma inlet 106. Similarly, the protection plate 114 is a quartz-made circular plate having a rectangular opening at a location corresponding to the microwave window 110. In addition, the protection plate 114 also has an opening for introducing an argon gas into the plasma chamber 107.

The protection tube 2 takes a tubular shape conforming to an inner shape of the plasma chamber 107, and inserted in the plasma chamber 107. The structure of the protection tube 2 will be described later in detail.

2. Operations of ECR Sputtering Apparatus 1

Similarly to the ECR sputtering apparatus 6, the ECR sputtering apparatus 1 carries out film-forming processing in a following manner.

First, a gas present inside the film-forming chamber 101 is evacuated by suction through the discharge outlet 102, so that a vacuum is produced in the film-forming chamber 101 and the plasma chamber 107. In addition, water present in the film-forming chamber 101 and the plasma chamber 107 is removed, followed by introduction of an argon gas thereto.

Next, the microwave 108 is introduced into the plasma chamber 107 from the waveguide tube 109 through the microwave window 110. On the introduction of the microwave 108, the exciting coil 112 generates a magnetic field in the plasma chamber 107, which causes an electron cyclotron resonance discharge. Consequently, a high-density plasma is generated within the plasma chamber 107, and argon ions are subsequently generated.

Being positively charged, the resulting argon ions are attracted to and collide with the metal target 105 which is at negative potential. The collisions sputter silicon atoms from the metal target 105. The silicon atoms sputtered from the metal target 105 deposit on the sample 103.

In addition, some of the silicon atoms sputtered from the metal target 105 react with gas-phase molecules present in the film-forming chamber 101, thereby generating new molecules. These molecules also deposit on the sample 103. Through the operations described above, the film-forming processing is carried out to form a thin-film on the sample 103.

3. Structure of Protection Tube 2

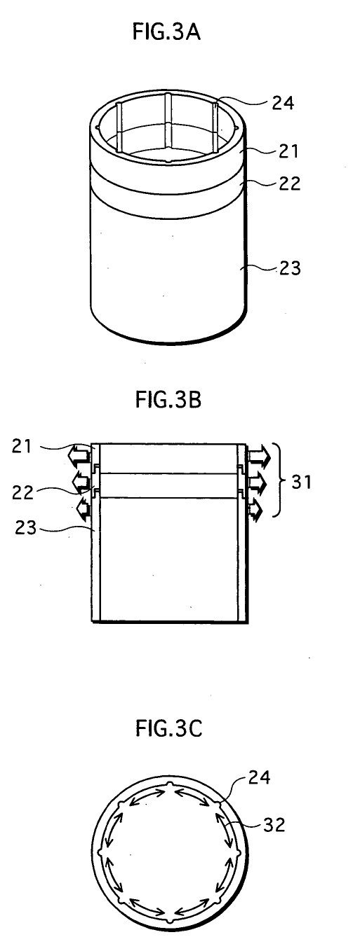

Next, description is given in detail to the structure of the protection tube 2. FIGS. 3 are views showing the structure of the protection tube 2. To be more specific, FIG. 3A is an external oblique view of the protection tube 2, FIG. 3B is a cross-sectional view of the protection tube 2 taken along a plane containing the tube axis, and FIG. 3C is a top view showing the protection tube 2 seen from the direction of the film-forming chamber 101.

As shown in FIG. 3A, the protection tube 2 is composed of three sub-tubes that are a top tube 21, a middle tube 22, and a bottom tube 23. Among the three sub-tubes, the bottom tube 23 is the longest in tube length, which in this embodiment is 144 mm.

Comparing to the bottom tube 23, the top tube 21 and the middle tube 22 are shorter, which are 10 mm and 12 mm, respectively. As shown in FIG. 3A, the top tube 21 and the middle tube 22 are provided with eight grooves 24 formed on the inner wall thereof. The grooves 24 extend in parallel with the tube axis, and each groove 24 is uniformly 3 mm in width and 0.5 mm in depth.

As shown in FIG. 3B, the top tube 21 is wider in the inside diameter at a part adjacent to the middle tube 22 (hereinafter, such a part is referred to as a “wider-inside diameter part”). Further, the middle tube 22 is narrower in the outside diameter at a part adjacent to the top tube 21 (hereinafter, such a part is referred to as a “narrower-outside diameter part”).

The middle tube 22 and the top tube 21 are joined together by loosely inserting the narrower-outside diameter part into the wider-inside diameter part.

Similarly, the middle tube 22 has a wider-inside diameter part adjacent to the bottom tube 23, and the bottom tube 23 has a narrower-outside diameter part adjacent to the middle tube 22. The bottom tube 23 and the middle tube 22 are joined together by loosely inserting the narrower-outside diameter part into the wider-inside diameter part.

4. Properties of Protection Tube 2

(1) As described above, the film-forming processing causes a sharp temperature gradient across the plasma chamber 107. Especially, the difference in the temperatures between the plasma chamber 107 and the film-forming chamber 101 is relatively large, so that the protection tube 2 exhibits a sharper temperature gradient at a part closer to the film-forming chamber 101.

Due to the temperature gradient, the protection tube 2 undergoes greater thermal expansion at a part closer to the film-forming chamber 101 than a part farther away from the film-forming chamber 101.

FIG. 3B illustrates the above mechanism. As shown in FIG. 3B, each sub-tube constituting the protection tube 2 is subjected to a thermal stress 31 to a degree corresponding to the distance from the film-forming chamber 101. In other words, the thermal stress is larger at a location closer to the film-forming chamber 101, and smaller at a location farther away from the film-forming chamber 101.

To accommodate the difference in the thermal stress, the protection tube 2 of the present embodiment is composed of the three sub-tubes which are joined together by loosely inserting one into another. This structure allows each sub-tube to freely expand despite the difference in thermal expansion among the sub-tubes. Accordingly, no internal stress is produced between the sub-tubes even if the sub-tubes thermally expand, and thus no thermal fatigue is caused.

Consequently, the protection tube 2 is free from breakage that results from thermal fatigue. Since breakage of the protection tube 2 is prevented, there is no scattering of silicon oxide deposit on the protection tube 2 or of quartz constituting the protection tube 2. The ECR sputtering apparatus 1 is thus capable of maintaining excellent film-forming capability.

(2) Focusing now to each sub-tube, there is a film formed over the internal surface of the sub-tube by deposition of silicon oxide and other products. This deposition film also expands when exposed to heat. The thermal expansion of the deposition film develops a stress 32 applied inside the sub-tube as shown in FIG. 3C.

To accommodate the stress 32, the sub-tubes according to the present embodiment are provided with the grooves on the inner walls thereof as described above. The grooves absorb distortion caused by the stress 32 that results from the thermal expansion of the deposition film. Consequently, breakage of the protection tube 2 is prevented, so that the ECR sputtering apparatus 1 is capable of maintaining an excellent film-forming capability.

(3) To be further noted is that the top tube 21 is more prone to breakage than the middle tube 22 and the bottom tube 23 as the top tube 21 receives a larger thermal stress because of the large difference in temperatures between the film-forming chamber 101 and the plasma chamber 107. For the same reason, the middle tube 22 is more prone to breakage than the bottom tube 23. According to the present embodiment, if the protection tube is broken, what needs to be replaced is only a sub-tube that is broken.

That is to say, unlike the conventional technique described above, it is not necessary to replace the entire protection tube. Consequently, the cost required for protecting the ECR sputtering apparatus from deposition is reduced.

5. Modifications

Up to this point, the present invention has been described by way of the above embodiment. However, it is naturally appreciated that the present invention is not limited to the specific embodiment described above, and various modifications may be made as follows.

(1) In the above embodiment, the description mentions the specific lengths of the sub-tubes that constitute the protection tube 2. However, it is naturally appreciated that the present invention is not limited to those specific lengths. The effect of the present invention is achieved irrespective of the dimensions of the sub-tubes as long as the protection tube is composed of a plurality of sub-tubes.

It is desirable to determine the lengths of each sub-tube according to the temperature distribution across the protection tube caused at the time when the ECR sputtering apparatus 1 performs the film-forming processing. To be more specific, it is desirable to determine the length of each sub-tube so that the temperature difference across an entire sub-tube falls within a predetermined range.

When the length of each sub-tube is determined as above, a thermal stress applied to each sub-tube is made smaller, so that the sub-tubes are less prone to breakage due to thermal fatigue. Consequently, the useful life of the protection tube is increased, thereby reducing the cost required for the film-forming processing by the ECR sputtering apparatus 1.

(2) In the above embodiment, the description is given to the protection tube 2 that is specifically composed of three sub-tubes. However, it is naturally appreciated that the present invention is not limited thereto. The effect of the present invention is achieved as long as the protection tube is composed of two or more sub-tubes.

Similarly to the determination of the lengths of sub-tubes, it is desirable to determine the numbers of sub-tubes constituting the protection tube according to the temperature distribution across the protection tube caused at the time of the film-forming processing by the ECR sputtering apparatus 1.

That is, when the temperature gradient caused at the time of the film-forming processing by the ECR sputtering apparatus 1 is relatively gentle across the inner wall of the protection tube, it may be sufficient to constitute the protection tube with a smaller number of sub-tubes. On the other hand, when the temperature gradient is relatively steep, it maybe desirable to constitute the protection tube with a greater number of sub-tubes.

When the number of sub-tubes is determined in the above manner, a thermal stress applied to each sub-tube is reduced, so that the sub-tubes are made less prone to breakage by thermal fatigue. Consequently, the useful life of the protection tube is increased, thereby reducing the cost required for the film-forming processing by the ECR sputtering apparatus 1.

(3) In the above embodiment, there are eight grooves formed on the inner wall of a sub-tube. However, it is naturally understood that the present invention is not limited thereto. The effect of the present invention is achieved as long as at least one sub-tube is provided with at least one grove formed on the inner wall thereof.

Here, it is desirable to determine the number of grooves to be formed on a sub-tube according to the thickness and properties of a deposition film formed on the inner wall of the sub-tube. This is because a stress applied to a sub-tube differs depending on the thickness and properties of a deposition film. When the stress is relatively small, a smaller number of grooves may be sufficient. On the other hand, when the stress is relatively large, a greater number of grooves may be desirable.

In the above embodiment, the bottom tube 23 is not provided with any groove. However, it is naturally understood that the present invention is not limited thereto. It is applicable that every sub-tube is provided with one or more grooves.

Here, it is desirable that each sub-tube constituting a single protection tube be provided with the same number of grooves. Yet, in the case where a stress due to a deposition film applied to each sub-tube greatly differs from one another, it is possible to provide different number of grooves to each sub-tube correspondingly to the stress applied thereto.

Further, it is desirable when a sub-tube is to be provided with a plurality of grooves, the grooves are formed on the inner wall thereof at substantially equal circumferential intervals. With this arrangement, a stress applied to the inner wall of the sub-tube is uniformly distributed, so that the maximum value of the stress is kept lower. Consequently, the sub-tube is made less prone to breakage.

(4) In the above embodiment, a sub-tube located closer to the film-forming chamber 101 is provided with a wider-inside diameter part, while a sub-tube located farther away from the film-forming chamber 101 is provided with a narrower-outside diameter part. Thus, the two sub-tubes are joined together by inserting the sub-tube located farther away from the film-forming chamber 101 into the other sub-tube. However, it is naturally appreciated that the present invention is not limited thereto. The sub-tubes may be joined together in a manner other than the one described above.

Reversely to the above embodiment, for example, a sub-tube located closer to the film-forming chamber 101 may be provided with a narrower-outside diameter part, while a sub-tube located farther away from the film-forming chamber 101 may be provided with a wider-inside diameter part. Thus, the two sub-tubes are joined together by inserting the sub-tube that is located closer to the film-forming chamber 101 into the other sub-tube.

Further, the sub-tubes may be joined together by way of miter joint instead of the foliated joint described above. Further, the sub-tubes may be joined together by way of rabbet joint if the wall thickness of the sub-tubes is suitable for such joint. The effect of the present invention is achieved irrespective of how the sub-tubes are joined together.

Considering the variations in the thermal expansion of the sub-tubes, it is desirable to join the sub-tubes together so as to provide an appropriate play between each sub-tube. By the presence of an appropriate play, the variations in the thermal expansion are accommodated, so that thermal fatigue is suppressed. Consequently, the effect of the present invention is achieved even to a better extent.

(5) In the embodiment described above, the present invention is described by way of the example of the ECR sputtering apparatus. However, it is naturally appreciated that applications of the present invention is not limited to the ECR sputtering apparatus. The present invention may be applied to any high-density plasma processing apparatus other than the ECR sputtering apparatus and still achieves the same effect.

To be more specific, the present invention may be applied to a plasma processing apparatus that generates an induction coupled plasma (ICP) or to a plasma processing apparatus that generates a helicon-wave excited plasma (HWP).

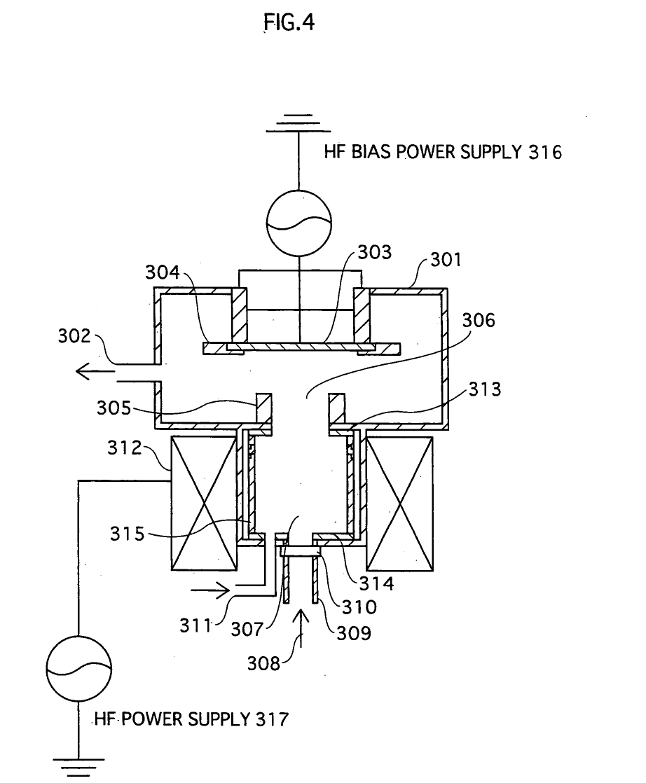

FIG. 4 is a cross-sectional view showing an ICP sputtering apparatus according to one modification of the present invention. As shown in FIG. 4, in the ICP sputtering apparatus, a coil 312 is provided to surround a plasma chamber 307. The sputtering is performed by an ICP that is generated through application of a high-frequency current to the coil 312.

The ICP sputtering apparatus is also provided with a protection tube 315 disposed in the plasma chamber 307, and the protection tube 315 is composed of a plurality of sub-tubes formed in relation to the temperature gradient at the time or the plasma processing. Similarly to the above embodiment, this structure achieves the effect of the present invention to make the protection tube 315 less prone to breakage.

The present invention is especially effective when applied to an apparatus that generates a plasma of which density exceeds 10¹⁰ ions/cm³ irrespective of schemes employed to generate the plasma, and achieves the effect of increasing the useful life of the apparatus.

(6) In the above embodiment, the present invention is described by way of the example of the ECR sputtering apparatus. However, it is naturally appreciated that applications of the present invention is not limited to the ECR sputtering apparatus. The present invention may be applied to any plasma processing apparatus other than the sputtering apparatus and still achieves the same effect.

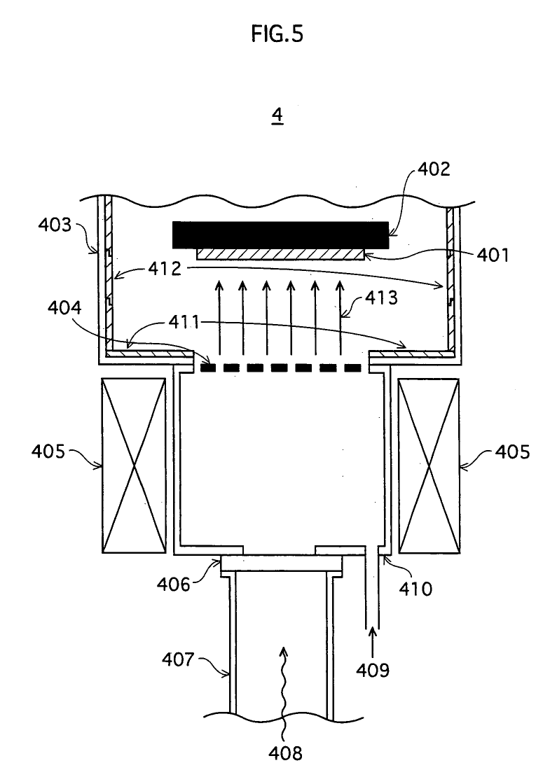

FIG. 5 is a cross-sectional view showing an exemplary reactive ion beam etching apparatus (hereinafter, referred simply as to “RIBE apparatus”) provided with a protection tube, according to another modification of the present invention.

As shown in FIG. 5, an RIBE apparatus 4 according to the present modification is composed of a sample stage 402, a sample chamber 403, an ion extraction electrode 404, an exciting coil 405, a microwave window 406, a waveguide tube 407, a plasma chamber 410, a protection plate 411, and a protection tube 412.

To operate the RIBE apparatus 4, first, the sample chamber 403 is evacuated. Then, a microwave 408 is introduced from the waveguide tube 407 through the microwave window 406 into the plasma chamber 410, and a material gas 409 is also introduced into the plasma chamber 410. The RIBE apparatus 4 then generates a magnetic field in the plasma chamber 410 by the action of the exciting coil 405, thereby generating a discharge by electron cyclotron resonance, and subsequently generating a high-density plasma.

Next, a negative potential is applied to the ion extraction electrode 404, so that reactive ions 413 are extracted from the plasma. Here, the sample stage 402 is made with a flat electrode, so that a DC electric field is generated on application of a high-frequency voltage to the sample stage 402. By the action of the thus generated electric field, the reactive element ions 413 are attracted vertically toward a sample (wafer) 401, so that anisotropic etching of the wafer 401 is performed.

As described above, at the time of performing the etching, it is required to protect the inner walls of the sample chamber 403 from deposition of useless materials. To this end, the circular protection plate 411 and the protection tube 412 are disposed inside the sample chamber 403.

Similarly to the ECR sputtering apparatus, the RIBE apparatus exhibits a big temperature difference between the sample chamber and the plasma chamber, which results in breakage of the protecting tube due to thermal fatigue.

To eliminate the above undesirable possibility, the protection tube 412 of the RIBE apparatus according to the modification is composed of a plurality of sub-tubes formed in relation to the temperature distribution caused at the time of the etching processing. With this arrangement, breakage of the protection tube is prevented, so that it is not necessary to replace the protection tube as frequently as that would otherwise be required. Consequently, the costs required for the etching processing is reduced.

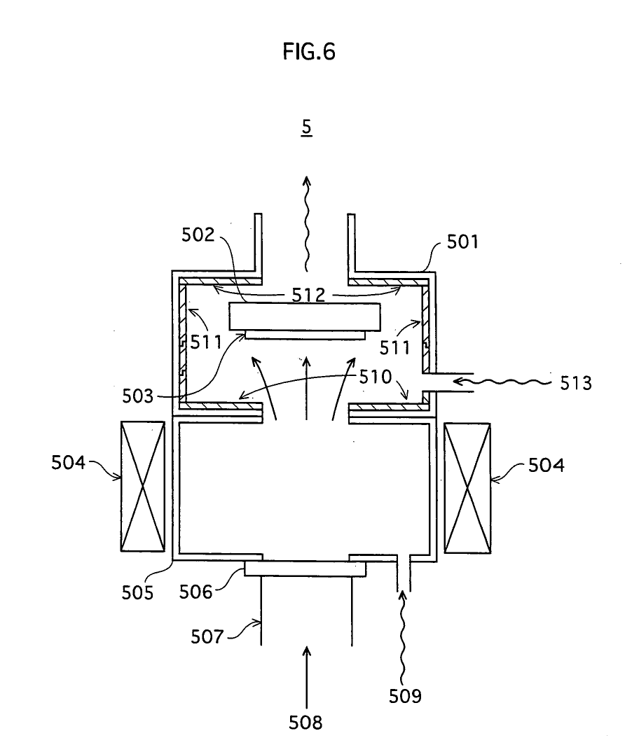

The present invention may also be applied to an ECR plasma CVD (Chemical Vapor Deposition) apparatus to achieve the same effect. FIG. 6 is a cross-sectional view showing the structure of an exemplary ECR plasma CVD apparatus according to the modification of the present invention.

As shown in FIG. 6, the ECR plasma CVD apparatus 5 is composed of a sample chamber 501, a sample stage 502, an exciting coil 504, a plasma chamber 505, a microwave window 506, a waveguide tube 507, protection plates 510 and 512, and a protection tube 511.

To operate the ECR plasma CVD apparatus 5, first, a gas present in the sample chamber 501 and the plasma chamber 505 are evacuated, so that a vacuum is produced therein. Next, the microwave 508 of 2.45 GHz frequency is introduced from a magnetron to the plasma chamber 505 through the waveguide tube 507 and the microwave window 506. Further, a nitrogen gas (N₂) is also introduced into the plasma chamber 505 as a material gas 509.

Under this condition, an magnetic field (875 G) is generated in the plasma chamber 505 by the action of the exciting coil 504, so that a high-density plasma is generated by electron cyclotron resonance. The resulting reactive gas molecules are guided to the sample chamber 501, and made to react with a silane gas (SiH₄) 513 that is separately introduced into the sample chamber 501. As a result of the reaction, a film of Si₃N₄ is formed on a sample (wafer) 503.

Similarly to the other apparatuses mentioned above, the protection plates 510 and 512 and the protection tube 511 are disposed in the sample chamber 501, so that the inner walls of the sample chamber 501 are protected from deposition of useless materials. Further, the protection tube 511 according to this modification is also composed of a plurality of sub-tubes formed in relation to the temperature distribution caused at the time of the ECR plasma CVD processing, so that the protection tube 511 is less prone to breakage due to the temperature difference between the sample chamber 501 and the plasma chamber 505.

With this arrangement, it is not necessary to replace the protection members as frequently as that would otherwise be required. Consequently, the cost of the ECR plasma CVD processing is reduced.

Note that the present invention is applicable to the above etching processing and the CVD processing performed using a plasma generated by any scheme such as ICP or HWP, other than ECR, and still achieves the same effect.

(7) In the above embodiment and modifications, the protection tubes and the protection plates are in contact with the inner walls of the plasma chamber or the sample chamber. However, it is naturally appreciated that the present invention is not limited thereto, and further modifications may be made as follows.

As described above, the protection tubes or the protection plates are disposed in order to protect the inner walls of the plasma chamber or the sample chamber from deposition of useless materials. That is, as long as such a protection is sufficiently provided, the outer dimensions of the protection tube may be smaller than the inner dimension of the plasma chamber or the sample chamber. Further, the area of the protection plate may be smaller than the area of the inner wall on which the protection plate is disposed.

The dimensions and shape of the protection tube or the protection plate may be determined to be suitable to the dimensions and shape of the plasma chamber or the sample chamber in which the protection tube or the protection plate is to be disposed. Regardless of the dimensions and shape, the protection tube is made less prone to breakage as long as the protection tube is composed of a plurality of sub-tubes. With this arrangement, it is not required to replace the protection tube as frequently as that would otherwise be required, so that running costs for the plasma processing apparatus is reduced.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. A plasma processing apparatus comprising:
a plasma chamber in which a high-density plasma is generated;
a sample chamber in communication with the plasma chamber for housing a sample to be processed using the plasma; and
a protection tube for protecting an inner wall of the plasma chamber from deposition of a product that results from the plasma processing, wherein
the protection tube is composed of a plurality of pieces formed in relation to a distribution of temperatures in the plasma chamber at a time of the plasma processing.

2. The plasma processing apparatus according to claim 1, wherein
the plasma chamber is tubular in shape,
the protection tube is tubular in shape and inserted in the plasma chamber, and
each of the plurality of pieces is a tubular member disposed in an axial direction of the protection tube.

3. The plasma processing apparatus according to claim 2, wherein
each of the plurality of pieces is shorter in length than a piece disposed at a location where a gradient of the temperatures at the time of the plasma processing is smaller.

4. The plasma processing apparatus according to claim 1, wherein
the protection tube is provided with at least one groove formed on an inner wall thereof in parallel with an axis of the protection tube.

5. The plasma processing apparatus according to claim 1, wherein
the protection tube is provided with a plurality of grooves formed on the inner wall thereof in parallel with an axis of the protection tube at substantially equal circumferential intervals.

6. The plasma processing apparatus according to claim 1, wherein
the protection tube is made of quartz.

7. The plasma processing apparatus according to claim 1, wherein
the sample is subjected to sputtering using the plasma.

8. The plasma processing apparatus according to claim 1, wherein
the plasma is an electron cyclotron resonance plasma.

9. The plasma processing apparatus according to claim 1, wherein
the plasma is an inductively coupled plasma.

10. The plasma processing apparatus according to claim 1, wherein
the plasma is a helicon wave plasma.

11. A plasma processing apparatus comprising:
a plasma chamber in which a high-density plasma is generated;
a sample chamber in communication with the plasma chamber for housing a sample to be processed using the plasma; and
a protection tube for protecting an inner wall of the sample chamber from deposition of a product that results from the plasma processing, wherein
the protection tube is composed of a plurality of pieces formed in relation to a distribution of temperatures in the sample chamber at the time of the plasma processing.

12. The plasma processing apparatus according to claim 11, wherein
the sample chamber is tubular in shape,
the protection tube is tubular in shape and inserted in the plasma chamber, and
each of the plurality of pieces is a tubular member disposed in an axial direction of the protection tube.

13. The plasma processing apparatus according to claim 12, wherein
each of the plurality of pieces is shorter in length than a piece disposed at a location where a gradient of the temperatures at the time of the plasma processing is smaller.

14. The plasma processing apparatus according to claim 11, wherein
the protection tube is provided with at least one groove formed on an inner wall thereof in parallel with an axis of the protection tube.

15. The plasma processing apparatus according to claim 14, wherein
the protection tube is provided with a plurality of grooves formed on the inner wall thereof in parallel with an axis of the protection tube at substantially equal circumferential intervals.

16. The plasma processing apparatus according to claim 11, wherein
the protection tube is made of quartz.

17. The plasma processing apparatus according to claim 11, wherein
the sample is subjected to etching using the plasma.

18. The plasma processing apparatus according to claim 11, wherein
the sample is subjected to chemical vapor deposition using the plasma.

19. The plasma processing apparatus according to claim 11, wherein
the plasma is an electron cyclotron resonance plasma.

20. The plasma processing apparatus according to claim 11, wherein
the plasma is an inductively coupled plasma.

21. The plasma processing apparatus according to claim 11, wherein
the plasma is a helicon wave plasma.
